(19) United States
(12) Patent Application Publication
(10) Pub. No.: US 2010/0149646 A1
(43) Pub. Date: Jun. 17, 2010

(54) DISPLAY FILTER REDUCING MOIRE PATTERNS AND REMOVING AIR POLLUTANTS

(75) Inventors: Ji Young Kim, ChungCheongNam-Do (KR); Moon Jin Choi, ChungCheongNam-Do (KR); Dae Chul Park, ChungCheongNam-Do (KR); Seok Won Kim, ChungCheongNam-Do (KR)

Correspondence Address: LERNER, DAVID, LITTENBERG,;KRUMHOLZ & MENTLIK, 600 SOUTH AVENUE WEST, WESTFIELD, NJ, 07090, US

(73) Assignee: SAMSUNG CORNING PRECISION GLASS CO., LTD., Gyeongsangbuk-do (KR)

(21) Appl. No.: 12/638,058

(22) Filed: Dec. 15, 2009

(30) Foreign Application Priority Data
Dec. 17, 2008 (KR) 10-2008-0128329

(51) Int. Cl. G02B 1/11; H05K 9/00

(52) U.S. Cl. 359/601; 361/818

(57) ABSTRACT

A display filter for a display device can reduce moiré patterns and remove air pollutants. The display filter includes a transparent substrate located in front of a display module of the display device and an anti-glare layer provided at a front of the display filter which is exposed to the outside. The anti-glare layer contains photo-catalyst particles as filler.

### CROSS REFERENCE TO RELATED APPLICATION

The present application claims priority from Korean Patent Application Number 10-2008-0128329 filed on Dec. 17, 2008, the entire contents of which are incorporated herein for all purposes by this reference.

### BACKGROUND OF THE INVENTION

1. Field of the Invention

The present invention relates to a display filter capable of reducing moiré patterns and removing air pollutants.

2. Description of Related Art

In response to the emergence of the advanced information society, components and devices related to photo-electronics have been significantly improved and rapidly distributed. Among them, image-displaying devices have been widely distributed for use in TVs, Personal Computer (PC) monitors and the like. Moreover, attempts are underway to increase the size and at the same time, reduce the thickness of such display devices.

In general, a Plasma Display Panel (PDP) device is advantageous since it can have a large size and a thin profile when compared to a Cathode Ray Tube device, which is representative of conventional display devices. The PDP device displays an image using gas discharge, and has excellent display properties, namely: display capability, luminance, contrast, after-image characteristics, and viewing angle.

However, the PDP device produces a large amount of Electromagnetic Interference (EMI) and Near Infrared (NIR) Radiation, attributable to its driving characteristics. Moreover, the PDP device is highly reflective, which is attributable to fluorescent material. In addition, because orange light is emitted by discharge gas, the color purity of the PDP device is inferior to that of a Cathode Ray Tube (CRT).

In order to overcome these problems, the PDP device employs a display filter including optical films having various functions, such as an EMI shielding function, an NIR cutting function, an anti-reflection function, and/or a color purity improving function, to block EMI and NIR radiation, reduce reflections, and improve color purity, respectively.

However, some of the optical films of the display filter have lattices or patterns formed thereon. The lattices or patterns of the optical films of the display filter cause interference, thereby creating moiré patterns. In the related art, an anti-glare film, which increases the amount of haze to reduce the moiré patterns, is attached to the display filter for the PDP device. The anti-glare film is attached to the backside of the display filter, which is adjacent to the display module.

In addition, due to consumers' increasing concern for environmental friendliness, well-being, and health, consumer's demands for the removal of indoor pollutants are rising. Accordingly, it is necessary to develop a display device that can satisfy the consumer's demands, in addition to the display function.

The information disclosed in this Background of the Invention section is only for the enhancement of understanding of the background of the invention and should not be taken as an acknowledgment or any form of suggestion that this information forms a prior art that would already be known to a person skilled in the art.

### BRIEF SUMMARY OF THE INVENTION

Various aspects of the present invention provide a display filter capable of reducing moiré patterns, which are generated from a display device, and removing air pollutants, which would otherwise pollute the indoor air.

Also provided is a display filter capable of removing moisture from the surface thereof.

In an aspect of the present invention, the display filter for a display device having a display module may include a transparent substrate located in front of the display module and an anti-glare layer provided at a front of the display filter, the front being exposed to the outside. The anti-glare layer may contain photo-catalyst particles as filler.

In an exemplary embodiment of the invention, the anti-glare layer may also contain an absorbing agent, which absorbs harmful chemicals in the air.

According to the exemplary embodiments of the present invention as set forth above, since the anti-glare layer containing photo-catalyst particles as filler is formed at the front of the display filter which is exposed to the outside, the display filter can reduce moiré patterns produced by the display device and at the same time, remove indoor air pollutants through a photo-catalytic reaction.

In addition, since the surface of the display filter becomes super-hydrophilic as a consequence of the photo-catalytic reaction, it is possible to automatically remove moisture from the surface of the display filter.

The methods and apparatuses of the present invention have other features and advantages which will be apparent from, or are set forth in greater detail in, the accompanying drawings, which are incorporated herein, and in the following Detailed Description of the Invention, which together serve to explain certain principles of the present invention.

### BRIEF DESCRIPTION OF THE DRAWINGS

FIG. 1 is a cross-sectional view schematically showing the configuration of a display device having a display filter according to an exemplary embodiment of the invention; and

FIG. 2 is a cross-sectional view schematically showing a display filter according to another exemplary embodiment of the invention.

### DETAILED DESCRIPTION OF THE INVENTION

Reference will now be made in detail to various embodiments of the present invention(s), examples of which are illustrated in the accompanying drawings and described below. While the invention(s) will be described in conjunction with exemplary embodiments, it will be understood that the present description is not intended to limit the invention(s) to those exemplary embodiments. On the contrary, the invention(s) is/are intended to cover not only the exemplary embodiments, but also various alternatives, modifications, equivalents and other embodiments that may be included within the spirit and scope of the invention as defined by the appended claims.

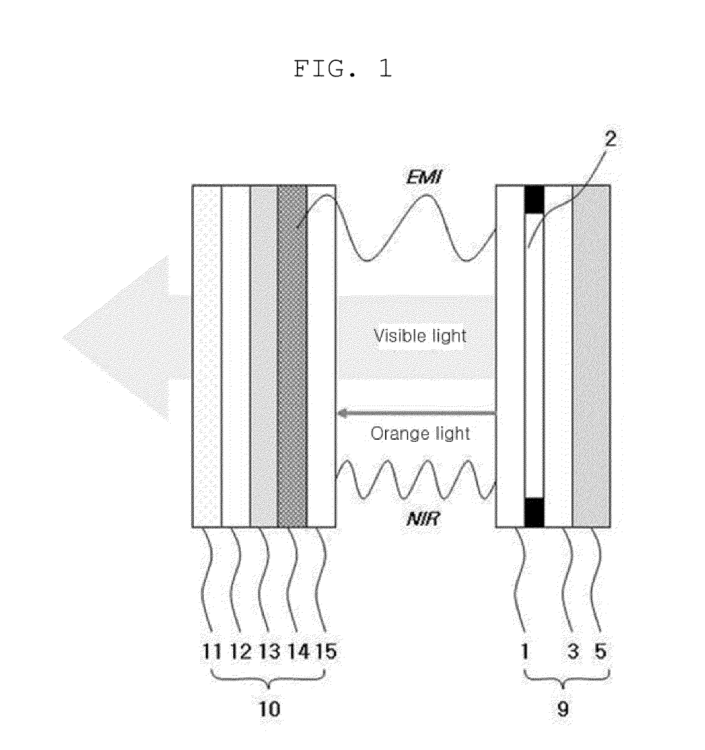

FIG. 1 is a cross-sectional view schematically showing the configuration of a display device having a display filter 10 of this exemplary embodiment.

As shown in FIG. 1, the display device having the display filter 10 of this exemplary embodiment may be a Plasma Display Panel (PDP) device. The PDP device has a discharge cell 2 provided between first and second substrates 1 and 3. The discharge cell 2 is filled with a mixture gas. In addition, a fluorescent material is applied on the inner wall of the discharge cell 2. In the PDP device, when a strong electric field is applied through a driving circuit board 5 to the mixture gas in the discharge cell 2, Ultraviolet (UV) rays emitted from the mixture gas strike the fluorescent material, and then visible light plus Electromagnetic Interference (EMI), Near-Infrared (NIR) Radiation, and orange light which deteriorates color purity are generated.

As shown in FIG. 1, the display filter 10 for the PDP device is provided in front of a display module 9. The display filter 10 shown in FIG. 1 includes an NIR cutting layer 15, an EMI shielding layer 14, a transparent substrate 13, an anti-reflection layer 12, and an anti-glare layer 11.

The anti-glare layer 11 is made of a transparent resin into which a photo-catalyst is mixed as filler. The transparent resin can be a resin which is usable as a hard coating material, that is, which can be used to form a hard coating layer. For example, some resins, such as acrylic resins, urethane resins, epoxy resins, and the like, which have high abrasion resistance due to high hardness, can be used. The resultant haze of the display filter is determined by the quantity of photo-catalyst particles. The anti-glare layer 11 reduces moiré patterns occurring in the display device which is provided with the display filter 10. The photo-catalyst particles create protrusions and depressions on the surface of the anti-glare layer 11. By way of example, the photo-catalyst particles can be made of one selected from among titanium oxide, strontium titanate, barium titanate, sodium titanate, zirconium dioxide, tungsten oxide, cadmium sulfide, zinc sulfide, and the like.

The photo-catalyst particles contained in the anti-glare layer can serve to remove microorganisms and mold via a photo-catalytic reaction. For example, when a titanium dioxide crystal absorbs a sufficient amount of light energy, electrons are transited to a conduction band and holes are created in a valence band. Such electron-hole pairs produce hydroxyl radicals and superoxide radicals, which can oxidize all organic materials existing on the surface of the titanium dioxide into CO₂ and H₂O.

In addition, the anti-glare layer 11 can also contain an absorbing agent, which absorbs harmful chemicals in the air. The absorbing agent used in this exemplary embodiment can be, for example, active carbons or zeolites. Zeolites are microporous crystalline solids with well-defined structures. Generally they contain silica and alumina in their framework and cations, water molecules, or other molecules within their pores.

The anti-glare layer 11 can also contain an antibiotic substance, which destroys harmful microorganisms. The anti-biotic substance used in this exemplary embodiment can be made of metal particles such as Ag, Cu, or the like. The metals, such as Ag and Cu, have the antibiotic effect and at the same time, can improve charge separation efficiency.

The anti-reflection layer 12 improves visibility by preventing external light from being reflected. The anti-reflection layer 12 can be a single layer having, for example, a thickness of a quarter of a wavelength of light, produced by forming a thin film using one selected from among fluorinated transparent polymer resin, magnesium fluoride, silicon-based resin, silicon oxide, and the like. In addition, the anti-reflection layer 12 can be formed by stacking two or more layers of thin films having different refractive indices, in which each thin film can be made of an inorganic compound, such as metal oxides, fluorides, silicides, borides, carbides, nitrides, sulfides, or the like; or an organic compound, such as silicone resins, acryl resins, fluorine resins, or the like.

The transparent substrate 13 is a base on which one or more optical films are stacked, and can be made of heat-strengthened glass or transparent polymer. Available examples of the transparent polymer may include, but are not limited to, Polyethylene Terephthalate (PET), acryl, Polycarbonate (PC), urethane acrylate, polyester, epoxy acrylate, brominate acrylate, Polyvinyl Chloride (PVC), and the like.

The EMI shielding layer 14 blocks harmful EMI radiation which is emitted from the display module 9. By way of example, the EMI shielding layer 14 can have structure of a multi-layer transparent conductive film, in which metal thin films and highly refractive transparent films are stacked on one another. In another example, the EMI shielding layer 14 can be a conductive mesh film in which a metal pattern is formed. The multi-layer transparent conductive film has an NIR cutting function. Accordingly, when the multi-layer transparent conductive film is used as the EMI shielding layer 14, the display filter 10 of this exemplary embodiment can block not only EMI radiation but also NIR radiation without an additional NIR cutting layer.

The NIR cutting layer 15 blocks NIR radiation, which would otherwise cause electronic devices, such as mobile phones and remote controls, to malfunction. The material capable of absorbing NIR radiation can be one or more selected from mixed colorants in which Ni complex and diimmonium are mixed, compound colorants containing Cu ions and Zn ions, cyanine-based colorants, anthraquinone-based colorants, squarylium-based compounds, azomethine-based compounds, okisonol compounds, azo-based compounds, benzylidene-based compounds, and the like.

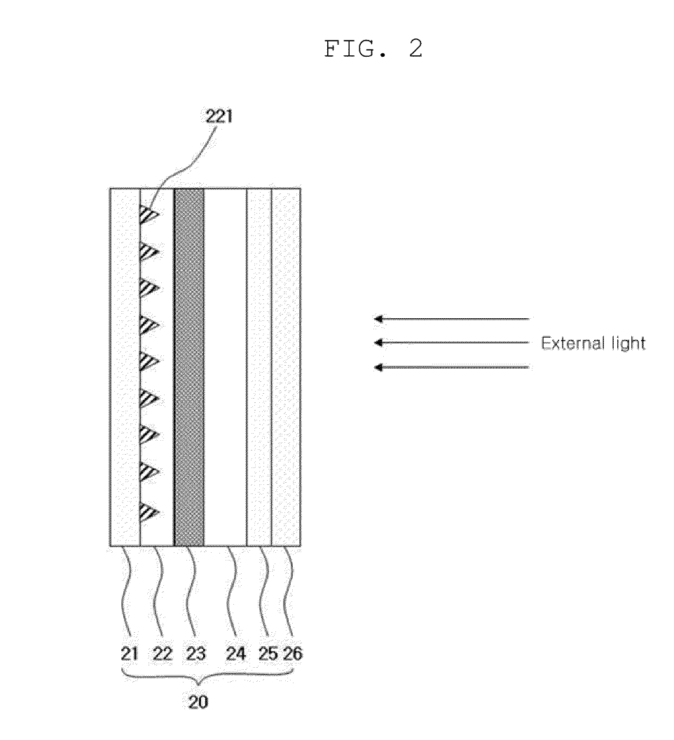

FIG. 2 is a cross-sectional view showing a display filter 20 according to another exemplary embodiment of the invention.

As shown in FIG. 2, the display filter 20 of this exemplary embodiment includes a color control layer 21, an external light-shielding layer 22, an EMI shielding layer 23, a transparent substrate 24, an anti-reflection layer 25, and an anti-glare layer 26.

In the PDP device, red visible light tends to discolor into orange light. The color control layer 21 increases the color reproduction range and at the same time, improves the clearness of image. The color control layer 21 changes or corrects color balance by reducing or adjusting the amount of red (R), green (G), and blue (B) light.

The external light-shielding layer 22 blocks external environmental light from penetrating into a display module (not shown). The external light-shielding layer 22 has a plurality of wedge-like black stripes 221, arranged parallel to one another, on one side thereof. The black stripes 221 absorb external environmental light but totally reflect light emitted from the display module (not shown), toward the viewers. The black stripes 221 can be made of various materials such as an inorganic substance, an organic substance, and a metal, as long as they can absorb light. When the black stripes 221 are made of metal powder having some electrical conductivity, the black stripes 221 can contribute to an EMI shielding function, wherein their electric resistance can be adjusted according to the concentration of the metal powder.

Table 1 below presents the results obtained by measuring the hazes of PDP devices for each of the four cases, in which a display filter has both a general anti-glare film and an anti-glare layer containing photo-catalyst particles, in which a display filter has a general anti-glare film but no anti-glare layer containing photo-catalyst particles is provided, in which a display filter has an anti-glare layer containing photo-catalyst particles without a general anti-glare film, and in which a display filter has neither an anti-glare layer containing photo-catalyst particles nor a general anti-glare film.

A conventional display filter has a general anti-glare film without an anti-glare layer containing photo-catalyst particles. In contrast, a display filter according to the present invention may have an anti-glare layer containing photo-catalyst particles without a general anti-glare film. The display filter according to the present invention is tested to examine the degree by which moiré patterns are reduced.

TABLE 1

General
anti-glare film

| | | ◯ | X |
|---|---|---|---|
| Anti-glare layer | X | 11.7 | 7.95 |
| containing photo-catalyst | ◯ | 14.1 | 10.4 |
| particles | | | |

Referring to Table 1 above, the conventional display filter has a haze value of 11.7. In contrast, the display filter according to the present invention has a haze value of 10.4.

It can be appreciated that the display filter which has the anti-glare layer containing photo-catalyst particles formed at the front of the display filter shows moiré-reducing performance similar to that of the conventional display filter.

Although only a PDP device has been illustrated by way of example of the display device which is provided with the display filter of the invention, the display filter of the invention is also applicable to other types of display devices such as a Liquid Crystal Display (LCD), an Organic Light-Emitting Diode (OLED) device, and the like.

The foregoing descriptions of specific exemplary embodiments of the present invention have been presented for the purposes of illustration and description. They are not intended to be exhaustive or to limit the invention to the precise forms disclosed, and obviously many modifications and variations are possible in light of the above teachings. The exemplary embodiments were chosen and described in order to explain certain principles of the invention and their practical application, to thereby enable others skilled in the art to make and utilize various exemplary embodiments of the present invention, as well as various alternatives and modifications thereof. It is intended that the scope of the invention be defined by the Claims appended hereto and their equivalents.

What is claimed is:

1. A display filter for a display device having a display module, the display filter comprising:
a transparent substrate located in front of the display module; and
an anti-glare layer provided at a front of the display filter which is exposed to the outside, wherein the anti-glare layer contains photo-catalyst particles as filler.

2. The display filter according to claim 1, wherein the anti-glare layer further contains an absorbing agent, which absorbs harmful chemicals in the air.

3. The display filter according to claim 2, wherein the absorbing agent includes at least one of active carbon and zeolite.

4. The display filter according to claim 1, wherein the anti-glare layer further contains an antibiotic substance, which destroys harmful microorganisms.

5. The display filter according to claim 1, wherein the photo-catalyst particles are made of at least one selected from the group consisting of titanium oxide, strontium titanate, barium titanate, sodium titanate, zirconium dioxide, tungsten oxide, cadmium sulfide, and zinc sulfide.

6. The display filter according to claim 1, further comprising:
an electromagnetic interference-shielding layer, wherein the electromagnetic interference-shielding layer blocks electromagnetic interference radiation emitted from the display module; and
an external light-shielding layer having a plurality of wedge-like black stripes, wherein the black stripes block external environmental light directed toward the display module.

7. The display filter according to claim 6, wherein the electromagnetic interference-shielding layer comprises a mesh film with a metal mesh pattern.
